(19) United States
(12) Patent Application Publication
(10) Pub. No.: US 2024/0292544 A1
(43) Pub. Date: Aug. 29, 2024

(54) METHOD OF MANUFACTURING THE PRINTED CIRCUIT BOARD EMBEDDED WITH WAFER LEVEL COMPONENT

(71) Applicant: DAEDUCK ELECTRONICS CO., LTD., Gyeonggi-do (KR)

(72) Inventors: Seon-Kyu CHANG, Seoul (KR); Hee-Il RYU, Anyang-si (KR)

(21) Appl. No.: 18/528,973

(22) Filed: Dec. 5, 2023

(30) Foreign Application Priority Data
Feb. 25, 2023 (KR) 10-2023-0025441

(51) Int. Cl. H05K 3/30; H05K 1/18; H05K 3/02

(52) U.S. Cl. CPC H05K 3/305; H05K 1/181; H05K 3/022; H05K 2201/10204

(57) ABSTRACT

The present invention discloses a fabrication method of thick-walled printed circuit board PCB), especially the packaging substrate for mounting thin wafer level components on the PCB substrate. The present invention provides a first embodiment of inserting a dummy at the circuit board manufacturing stage and a second embodiment of adjusting the thickness by inserting a dummy at the wafer processing stage.

### CROSS REFERENCE TO RELATED APPLICATION

This application claims priority under 35 USC § 119 to Korean Patent Applications No. 10-2023-0025441 (Filing Date: Feb. 25, 2023), the contents of which are incorporated herein by reference in their entirety. The list of the prior art is the following: Korean Patent Publication No. 10-2009-0111380, and Korean Patent Publication No. 10-2010-0006946.

### FIELD OF THE INVENTION

The present invention relates to a method of manufacturing a printed circuit board (PCB) and more particularly a method of fabricating a package substrate in which a wafer level component is embedded.

### BACKGROUND OF THE INVENTION

As electronic circuits become denser and more heavily integrated, the technology of mounting or embedding semiconductor chips directly either on or inside the printed circuit boards, especially package substrates, at wafer level is becoming important. In the following, wafer-level chips that are mounted or embedded directly on/in the circuit board will be called wafer level components.

In general, in order to embed a wafer level component into a substrate, a cavity is fabricated on copper clad laminate (CCL), a wafer level component is mounted in the cavity, and an electrical connection is made to the substrate using micro-via processing technology and plating technology.

In recent years, as the laminated circuit board has become multi-layered, the thickness of the copper lad laminate has become thicker. However, since the thickness of the wafer level component to be mounted on the copper clad laminate is maintained at a constant height (e.g., about 0.6 mm), technical difficulties arise in the circuit board manufacturing process if the difference between the thickness of the copper clad laminate and the wafer level component is significant.

### SUMMARY OF THE INVENTION

Accordingly, the purpose of the present invention is to provide a circuit board manufacturing method for mounting a wafer level component into a cavity on a copper clad laminate of a thickness exceeding the thickness of the wafer level component.

In order to achieve the above purpose, the present invention is characterized by the insertion of a dummy overcoming the difference in the thickness of the wafer level component and the cavity, and the present invention provides two embodiments, a first embodiment of inserting a dummy in the circuit board fabrication stage and a second embodiment of inserting a dummy in the wafer processing stage.

The first embodiment of the present invention comprises steps of: (a) performing a drilling process on a substrate to form a cavity of a predetermined size that penetrates from the upper surface down to the lower surface; (b) attaching an adhesive tape to the lower surface of the substrate; (c) inserting the wafer level component into the cavity and settling the wafer level component on the adhesive tape; (d) applying an adhesive-component material on top of the upper surface of the wafer level component which is now seated on the adhesive tape; (e) attaching a dummy chip to the adhesive-component material so that the dummy chip is adhered to the wafer level component wherein the dummy chip height level is aligned to the same level as the height level of the copper clad laminate plate after the attachment; (f) attaching a first insulating layer is formed on the whole upper surface of the substrate wherein the dummy chip is glued; (g) removing the adhesive tape at the lower surface of the substrate; and (h) attaching a second insulating layer on the whole lower surface of the substrate wherein the adhesive tape is removed.

The second embodiment of the present invention consists of steps of: (a) performing a drilling process on a substrate to form a cavity of a predetermined size that penetrates from the upper surface down to the lower surface; (b) attaching an adhesive tape to the lower surface of the substrate; (c) either attaching an adhesive tape or applying adhesive-component material on the whole surface of the dummy wafer; (d) stacking and gluing s a wafer on top of the dummy; (e) adjusting the thickness of the structure of the step (d) by grinding the lower surface of the structure and preparing a wafer level component through dicing; (f) inserting the wafer level component of the step (e) into the cavity and settling the wafer level component on the adhesive tape of the step (b); (g) removing the adhesive tape at the lower surface of the structure if (f); and (h) attaching an insulating layer on the whole surface of the substrate.

The present invention has the effect of being able to mount a wafer level component processed at a semiconductor company into a cavity without technical difficulty, even if the thickness of the copper-clad laminate becomes thicker, for example, 0.6 mm or more.

### BRIEF DESCRIPTION OF THE DRAWINGS

FIGS. 1a to 1k are cross-sectional drawings of the circuit board processing sequences showing the manufacturing method according to the first embodiment of the present invention.

FIGS. 2a to 2g are cross-sectional drawings of the circuit board processing sequences showing the manufacturing method according to the second embodiment of the present invention.

### DETAILED DESCRIPTION OF THE INVENTION

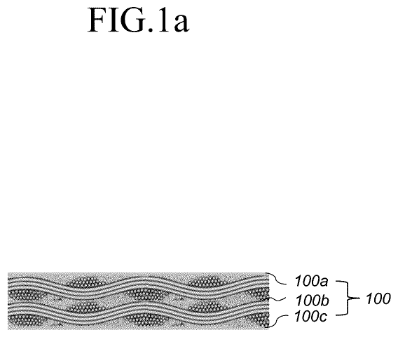

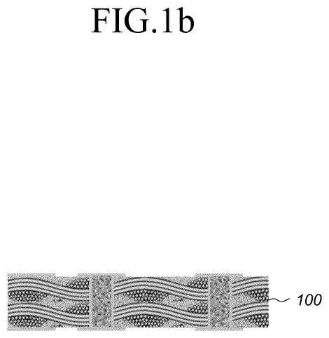

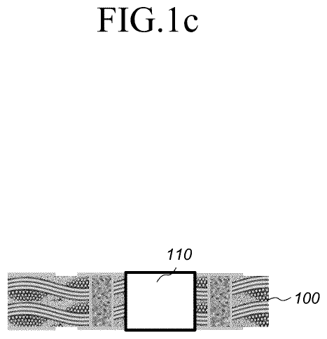

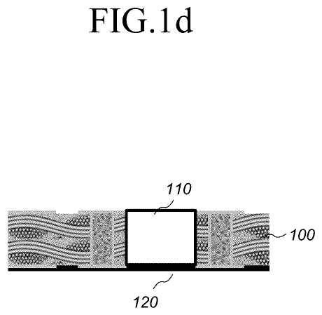

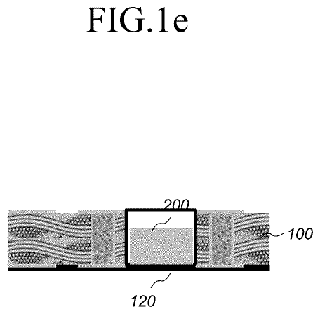

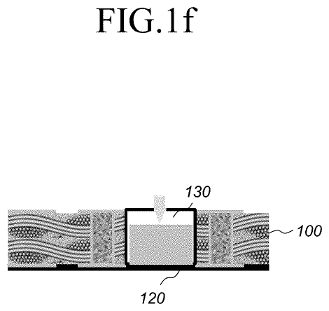

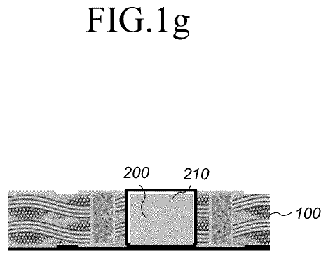

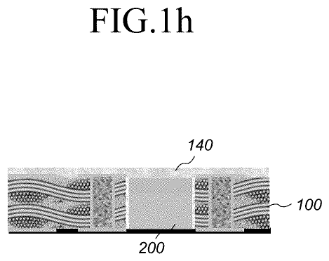

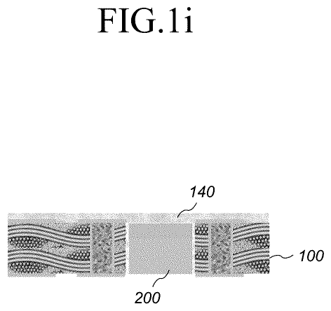

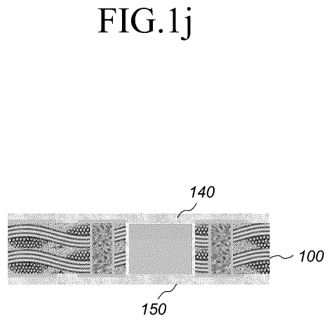

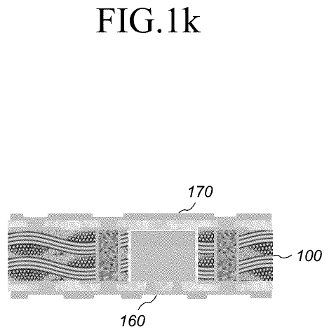

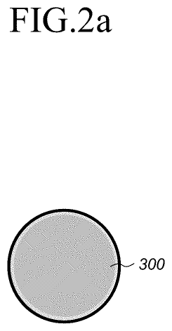

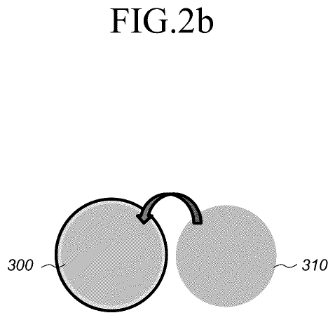

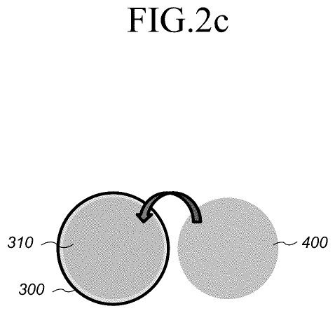

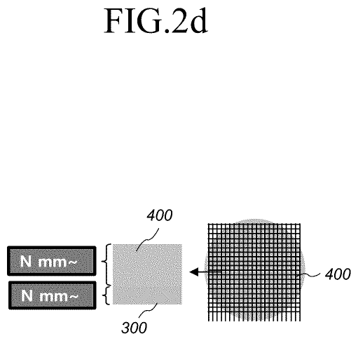

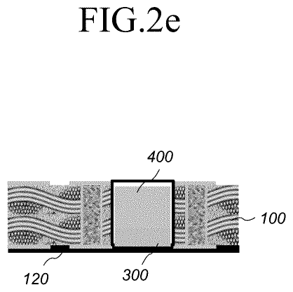

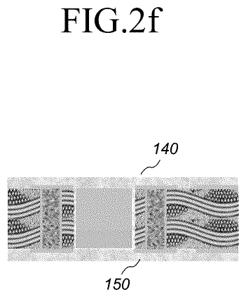

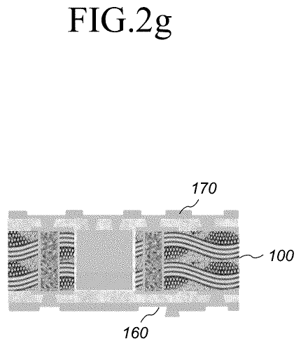

Detailed descriptions will be made on preferred embodiments and constitutional features of the fabricating method in accordance with the present invention with reference to attached figures from FIG. 1 and FIG. 2.

FIGS. 1a to 1k are cross-sectional drawings of the board processing process showing the circuit board manufacturing method according to the first embodiment of the present invention. The first embodiment of the present invention is characterized by inserting a dummy at the stage of circuit board manufacturing.

Referring to FIG. 1a, the copper clad laminate 100 is shown wherein the copper foil 100a, 100c is coated on both sides of the central insulating layer 100b. In the FIG. 1a, an unmachined copper-clad laminate (Bare CCL) is shown as a starting material, but we should note, as a preferred embodiment of the present invention, that the laminated substrate that has undergone a series of circuit pattern transfer processes such as photographing, development, etching, plating, and lamination processes may be also used as the starting material.

Referring to FIG. 1b, a series of circuit pattern transfer processes such as drilling, photography, development, etching, and plating are carried out to form a prescribed circuit on the top and bottom plates of copper clad.

Referring to FIG. 1c, the drilling process is carried out on the circuit board 100 to form a cavity 110.

Referring to FIG. 1d, an adhesive tape 120 is attached to the lower surface of the substrate. In other words, the adhesive tape 120 is attached to the bottom plate of the copper clad 100c. Consequently, the base of the cavity 110 is made by the sticky-side surface of the adhesive tape 120. Subsequently, referring to FIG. 1e, the wafer level component 200 is inserted into the cavity 110 and placed and fixed on the sticky-side surface of the adhesive tape 120.

Referring to FIG. 1F, the adhesive component material 130 is applied on the top surface of the wafer level component 200. Here, as a good embodiment of the adhesive component material 130 to be applied on the top surface of the wafer level component 200, a solid or liquid type of adhesive component material may be used.

Referring to FIG. 1g, a dummy chip 210 is attached onto the adhesive component material 130. At this time, as a preferred embodiment of the present invention, it is desirable that the thickness of the dummy chip 210 be cut so that it should be equal to the difference between the thickness of the copper clad laminate 100 and that of the wafer level component 200. Another preferred embodiment in accordance with the present invention it is desirable that the thickness of the dummy chip 210 be cut so that it should be equal to the difference between the height of the cavity 110 and the thickness of the wafer level component 200.

Referring to FIG. 1h, after settling the dummy chip 210 inside the cavity 110, a first insulating layer 140 is applied and formed on the surface of the upper plate 100a of the copper clad laminate 100. As a preferred embodiment of the first insulating layer 140 according to the present invention, a resin-based material such as PREPREG or ABF may be used. Now the structure of the dummy on the wafer level component inside the cavity is hold by the flow of the first insulating layer 140.

Referring to FIG. 1i, the adhesive tape 120 is now peeled off or removed by detach which was attached to the lower bottom surface of the substrate. Referring to FIG. 1j, a second insulating layer 150 is formed to the lower bottom surface of the substrate 100. As a good embodiment of the second insulating layer 150 according to the present invention, a resin-based material such as PREPREG or ABF may be used.

Referring to FIG. 1k, circuits 160 are formed on both upper and lower sides (top and bottom copper plates) of the board through the conventional circuit board fabrication process such as a pattern transfer process comprising photography, development, and etching. Thereafter, solder resist 170 (PSR) is printed for the protection of the circuit.

FIGS. 2A to 2G are cross-sectional drawings of the board processing process showing the circuit board manufacturing method according to the second embodiment of the present invention. The second embodiment of the present invention has a technical feature in a sense that the height control is made at the stage of fabricating the wafer in the semiconductor processing plants.

Referring to FIG. 2a, the dummy wafer 300 is prepared. As a preferred embodiment of the dummy wafer 300 according to the present invention, a pattern-less silicon wafer may be used. Alternatively, a polycrystalline or amorphous silicon wafer or other materials, even if they are not silicon, may be utilized.

Referring to FIG. 2b, the adhesive component material 310 is applied on the dummy wafer 300. As a good embodiment, a solid or liquid type of adhesive component substance may be applied or an adhesive tape may be sheathed.

Referring FIG. 2c, the processed silicon wafer 400 having integrated circuits is now seated via the adhesive component material 310 on top of the upper top surface of the dummy wafer 300. Thereafter, referring to FIG. 2d, the lower bottom surface of the dummy wafer is grinded so that the total thickness of the dummy wafer 300 and the actual silicon wafer 400 is the same as the vertical step of the cavity to be embedded, that is, the total thickness of the copper clad laminate. After grinding, dicing is carried out with a predetermined size to produce chips (wafer level components).

The subsequent process proceeds in the same way as the process of FIG. 1h to FIG. 1k described in the first embodiment of the present invention. In other words, referring to FIG. 2e, the adhesive tape 120 is pressed against the lower surface of the copper clad laminate formed by the cavity, and the polished and diced wafer level component is pushed into the cavity and settled on the adhesive tape 120.

At this time, it is noted that the vertical height, i.e., level of the wafer level component entrenched on the adhesive tape 120, is equal to the thickness of the copper clad laminate, i.e., the depth level of the cavity.

Referring to FIG. 2f, the upper and lower surfaces of the substrate are covered with an insulating layer 140, 150. At this time, as a good embodiment of the insulating layer a resin-based material such as PREPREG or ABF may be used.

Referring to FIG. 2G, opening are formed by selectively etching the insulating layer according to the circuit pattern. Copper plating is applied to the upper and lower front of the board, and the copper foil circuit of the upper and lower surfaces is formed through a series of pattern transfer processes such as photography, development, and etching. Then, solder resist (PSR) is applied on top of the copper foil to form a protective layer that protects the circuit.

In other words, a series of pattern transfer processes such as etching and plating can be carried out to transfer a predetermined circuit, forming a copper foil circuit that connects the buried wafer level component electrode with an external terminal, and then going through the steps of sheathing the solder resist.

The foregoing has been a rather extensive improvement of the features and technical advantages of the present invention in order to better understand the scope of the patent claims of the invention to be described later. The additional features and advantages that constitute the patent claims of the present invention will be detailed below. It should be recognized by those skilled in the field of the present that the concept an d specific embodiments of the present invention that have been disclosed can be readily used as the basis for the design or modification of other structures to perform purposes similar to the present invention.

Further in addition, the invention concept and embodiment disclosed in the present invention may be used by skilled persons in the field of the art as a basis for modifying or designing a different structure to accomplish the same purpose of the present invention. In addition, such modified or altered equivalence structure by a person skilled in the field of technology is subject to various evolutions, substitutions, and variations within the scope of the patent claims, as long as it does not go beyond the idea or scope of the invention described above. it will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

1. A fabricating method of the circuit board containing the wafer level component, comprising the steps of:
(a) preparing a substrate having conducting layers on both surfaces and drilling the substrate to form a cavity of a predetermined size that penetrates from the upper surface down to the lower surface;
(b) attaching an adhesive tape to the lower surface of the substrate;
(c) inserting the wafer level component into the cavity and settling the wafer level component on the adhesive tape;
(d) applying an adhesive component material on top of the upper surface of the wafer level component;
(e) attaching a dummy chip via the adhesive component material so that the dummy chip is adhered to the top surface of the wafer level component wherein the dummy chip height level is aligned to the height level of the copper clad laminate plate after the attachment;
(f) applying a first insulating layer on the whole upper top surface of the substrate wherein the dummy chip is glued;
(g) removing the adhesive tape at the lower surface of the substrate; and
(h) attaching a second insulating layer on the whole lower bottom surface of the substrate wherein the adhesive tape is removed.

2. A fabricating method of the circuit board containing the wafer level component, comprising the steps of:
preparing a substrate having conducting layers on both surfaces and drilling the substrate to form a cavity of a predetermined size that penetrates from the upper surface down to the lower surface;
(b) attaching an adhesive tape to the lower surface of the substrate;
(c) preparing a dummy wafer and attaching an adhesive tape or applying adhesive component material on the surface of dummy wafer;
(d) stacking and gluing a real wafer on top of the dummy wafer;
(e) adjusting the thickness of the structure of the step (d) by grinding the lower bottom surface of the structure and dicing the structure to get a wafer level component;
(f) inserting the wafer level component of the step (e) into the cavity and settling the wafer level component on the adhesive tape of the step (b);
(g) removing the adhesive tape at the lower surface of the structure; and
(h) attaching an insulating layer on the whole surface of the substrate.

3. The method as set forth in claim 1, characterized in that the substrate is copper clad laminate (CCL).

4. The method as set forth in claim 1, further comprises a pattern transfer process for forming the route which electrically connects the electrode of the embedded wafer level component to the outer circuit of the circuit board.
